(19) United States
(12) Patent Application Publication
(10) Pub. No.: US 2010/0155955 A1
(43) Pub. Date: Jun. 24, 2010

(54) METHOD FOR MANUFACTURING SYSTEM-IN-PACKAGE

(76) Inventor: Chung-Kyung Jung, Anyang-si (KR)

Correspondence Address: SHERR & VAUGHN, PLLC, 620 HERNDON PARKWAY, SUITE 320, HERNDON, VA, 20170, US

(21) Appl. No.: 12/620,115

(22) Filed: Nov. 17, 2009

(30) Foreign Application Priority Data
Dec. 19, 2008 (KR) 10-2008-0130154

(51) Int. Cl. H01L 23/498; H01L 21/98

(52) U.S. Cl. 257/768; 438/107; 257/741; 257/531; 257/532; 257/E21.705; 257/E23.072

(57) ABSTRACT

A method of manufacturing a System In Package (SIP) and devices thereof. A method of manufacturing a SIP may include providing a first chip having a first substrate region and/or a first metal connection portion. A method of manufacturing a SIP may include providing a second chip having a second substrate region and/or a second metal connection portion. A method of manufacturing a SIP may include bonding a first metal connection portion with a second metal connection portion, which may stack a second chip with a first chip. A method of manufacturing a SIP may include subjecting a second substrate region to reactive ion etching to expose a portion of a second metal connection portion and/or to form a deep contact hole. A method of manufacturing a SIP may include treating a surface of a deep contact hole with tetra-methyl ammonium hydroxide and/or nitric acid.

The present application claims priority under 35 U.S.C. 119 to Korean Patent Application No. 10-2008-0130154 (filed on Dec. 19, 2008) which is hereby incorporated by reference in its entirety.

### BACKGROUND

Embodiments relate to semiconductor devices and methods thereof. Some embodiments relate to a method of manufacturing a System In Package and devices thereof.

Developments in the electronic industry may have attempted to address user needs, which may include relatively smaller, lighter and/or multi-functional electronic products. Electronic product assembly technologies may have been developed to address such needs, and technologies under development may include substantially identical and/or different integrated circuit chips disposed on and/or over one module. New package technologies may be developed, and may include System on Chip (SoC) and/or System In Package (SIP). SIP may include a structure in which semiconductor chips, which may have a plurality of substantially different package functions, may be stacked in one package and/or may include a multi-layer form.

Semiconductor chips of a stacked structure may include metal connection portions bonded to one another, and/or deep contacts connected to respective metal connection portions. Semiconductor chips of a stacked structure may be connected to one another with deep contacts. In order to form a deep contact, a deep contact hole which passes through a semiconductor chip may be formed. Reactive ion etching (RIE) may be used. However, if a deep contact hole is formed by reactive ion etching, plasma may damage an inside portion of a contact hole. A side wall of a deep contact hole may also be affected, for example by heat transmitted from a bonded metal connection portion which may be exposed to a lower side of a contact hole.

Accordingly, there is a need of a method of manufacturing a System In Package and a System In Package that may improve a surface roughness of an inside portion of a deep contact hole which may be caused by plasma damage, for example at a time of formation of a deep contact hole. There is a need of a method of manufacturing a System In Package and a System In Package that may maximize dissipation of heat generated, for example at a time of bonding.

### SUMMARY

Embodiments relate to a method of manufacturing a System In Package and a System In Package. According to embodiments, a method of manufacturing a System In Package and a System In Package may improve a surface roughness of an inside portion of a deep contact hole which may be caused by plasma damage, for example at a time of formation of a deep contact hole. In embodiments, a method of manufacturing a System In Package and a System In Package may maximize dissipation of heat generated, for example at a time of bonding.

According to embodiments, a method of manufacturing a System In Package (SIP) may include providing a first chip having a first substrate region. In embodiments, a first metal connection portion may be formed on and/or over a first substrate region. In embodiments, a method of manufacturing a SIP may include providing a second chip having a second substrate region. In embodiments, a second metal connection portion may be formed on and/or over a second substrate region.

According to embodiments, a method of manufacturing a SIP may include bonding a first metal connection portion to a second metal connection portion and/or stacking a second chip on and/or over a first chip. In embodiments, a method of manufacturing a SIP may include subjecting a second substrate region to reactive ion etching (RIE). In embodiments, RIE may expose a portion of a second metal connection portion and/or form a deep contact hole. In embodiments, a method of manufacturing a SIP may include treating a surface of a deep contact hole with tetra-methyl ammonium hydroxide (TMAH) and/or nitric acid (HNO₃).

According to embodiments, a method of manufacturing an SIP may maximize uniformity of an inside surface of a deep contact hole, for example by treating an inside surface of a deep contact hole. In embodiments, treatment may include TMAH, which may include a relatively strong alkaline organic substance, and/or nitric acid HNO₃, which may include a relatively strong acidic substance. In embodiments, device characteristics may be maximized, for example by dissipating heat generated at a time of bonding. In embodiments, a contact including gold and/or silver may be formed which may include a relatively stronger reductive power than, for example, copper that may be used.

### DRAWINGS

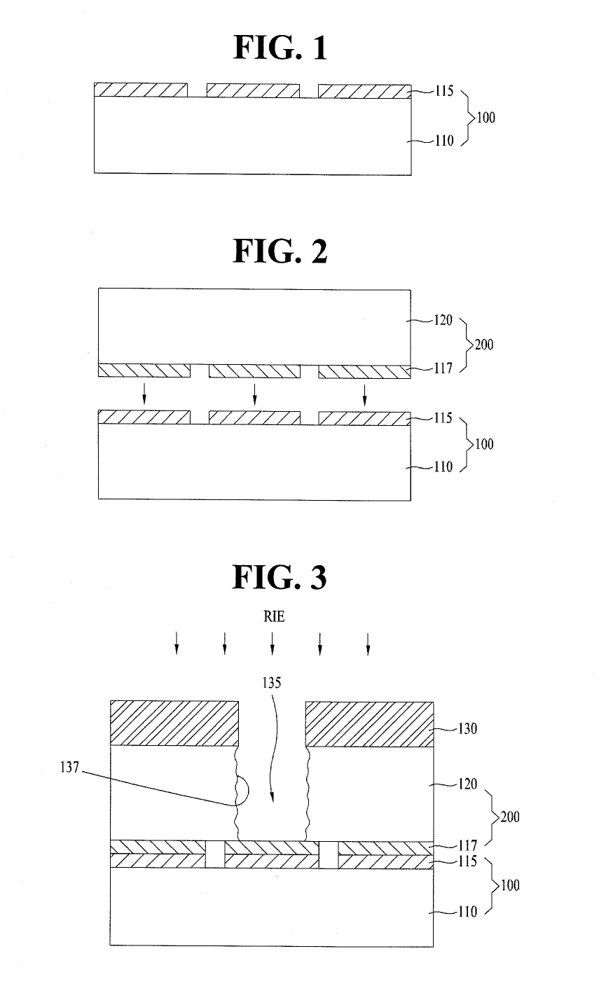

Example FIG. 1 to FIG. 5 are sectional views illustrating a method of manufacturing a System In Package in accordance with embodiments.

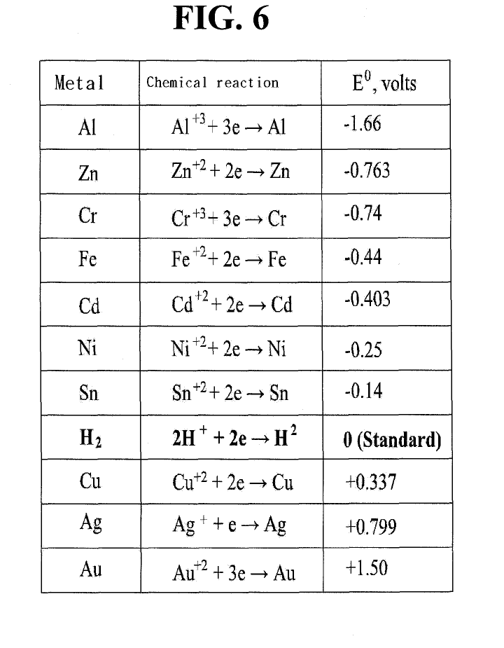

Example FIG. 6 is an example table illustrating ionization tendencies of metals in accordance with embodiments.

### DESCRIPTION

Embodiments relate to a method of manufacturing a System In Package (SIP). Referring to example FIG. 1 to FIG. 5, sectional views illustrate a method of manufacturing a SIP in accordance with embodiments. Referring to FIG. 1, first chip 100 may be provided. According to embodiments, first chip 100 may include a bottom chip of a SIP. In embodiments, first chip 100 may include first substrate region 110. In embodiments, first metal connection portion 115 may be formed on and/or over first substrate region 110.

According to embodiments, first substrate region 110 may include a semiconductor device, such as a transistor, an inductor and/or a capacitor. In embodiments, first substrate region may include an insulating layer, a metal line and/or a metal pad. In embodiments, first metal connection portion 115 may include copper, an alloy of copper and/or tin.

Referring to FIG. 2, second chip 200 may be provided. According to embodiments, second chip 200 may be bonded with first chip 100. In embodiments, second chip 200 may include second substrate region 120 and/or second metal connection portion 117. In embodiments, second metal connection portion 117 may be formed on and/or over an underside of second substrate region 120.

According to embodiments, second substrate region 200 may include a semiconductor device, such as a transistor, an inductor and/or a capacitor. In embodiments, second substrate region 200 may include an insulating layer, a metal line and/or a metal pad. In embodiments, second metal connection portion 117 may include copper, an alloy of copper and/or tin.

According to embodiments, first metal connection portion 115 of first chip 100 and second metal connection portion 117 of second chip 200 may be bonded by thermal compressive bonding, or the like. In embodiments, second chip 200 may be stacked with first chip 100. In embodiments, first metal connection portion 115 and/or second metal connection portion 117 may be heated at bonded portions in thermal compressive bonding. In embodiments, a SIP characteristic may be affected.

Referring to FIG. 3, photolithography may be performed. According to embodiments, photolithography may be performed at an upper portion of second chip 200, which may be stacked on and/or over first chip 100. In embodiments, photoresist pattern 130 may be formed. In embodiments, photoresist pattern 130 may be patterned to form a deep contact hole on and/or over second chip 200.

According to embodiments, second chip 200 may be etched using photoresist pattern 130 as an etch mask. In embodiments, etching substrate region 120 of second chip 200 may expose a portion of second metal connection portion 117. In embodiments, etching may include reactive ion etching. In embodiments, deep contact hole 135 may be formed. In embodiments, ashing and/or stripping may be performed to remove photoresist pattern 130, for example remaining after reactive ion etching.

According to embodiments, an inside surface of deep contact hole 135 may be damaged. In embodiments, inside sidewall 137 of deep contact hole 135 may be damaged, for example by plasma generated at a time of reactive ion etching. In embodiments, inside sidewall 137 of deep contact hole may be relatively rough and/or partly lost, for example by plasma attack.

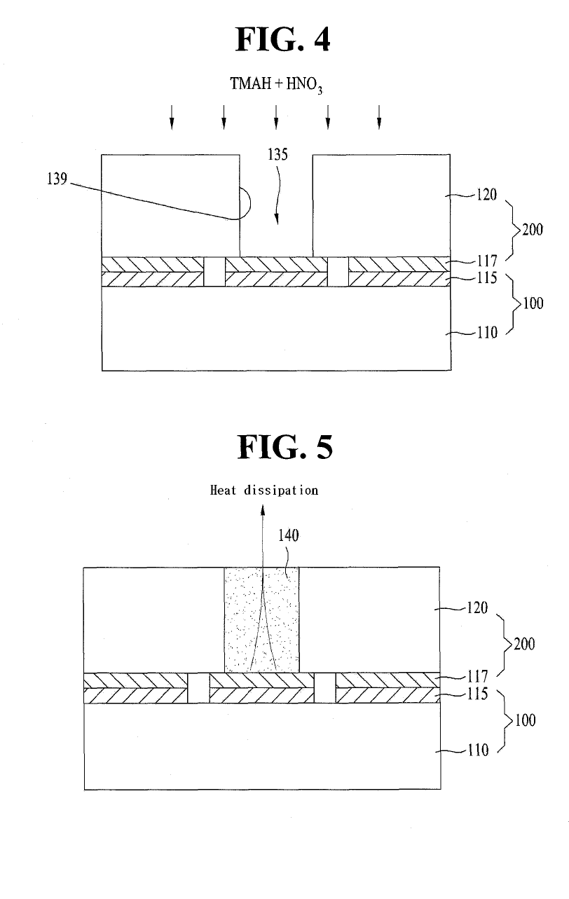

Referring to FIG. 4, a surface of deep contact hole 135 may be treated with tetra-methyl ammonium hydroxide (TMAH), which may include a strongly alkaline organic substance, and/or nitric acid (HNO₃), which may include a strong acid. In embodiments, a surface of deep contact hole 135 may be treated with TMAH and HNO₃ in succession. In embodiments, a surface treatment time period of TMAH may be longer relative to a surface treatment time period of HNO₃. In embodiments, to relatively improve surface roughness of deep contact hole 135, a surface of deep contact hole 135 may be treated with TMAH for between approximately 1 minute and 60 minutes, and/or a surface of the deep contact hole 135 may be treated with HNO₃ for less than approximately 1 minute.

According to embodiments, an inside surface, such as inside sidewall 137 of the deep contact hole, may become relatively rough and/or may be partly lost, for example by plasma attack. In embodiments, a surface of a deep contact hole may become substantially uniform by treating the surface in accordance with embodiments. In embodiments, uniform surface 139 may be formed. In embodiments, an inside surface of deep contact hole including silicon may include an increased roughness, for example by plasma attack which may be generated at a time of reactive ion etching, such that relatively many crystalline directions may be formed on and/or over a surface. In embodiments, energy may tend to go to a stabilizing direction, and/or at least one plane having a relatively high surface energy may be etched by TMAH and/or HNO₃. In embodiments, a surface may be etched such that a surface energy may relatively stabilize and/or to make a surface substantially uniform.

Referring to FIG. 5, a metal may be buried on and/or over deep contact hole 135. According to embodiments, deep contact 140 may be formed. In embodiments, metal used may be related to a metal of first metal connection portion 115 and/or second metal connection portion 117. Example FIG. 6 illustrates an example table of ionization tendencies of metals in accordance with embodiments. Units of numerals on a right side of the table are voltages (V). Numerals may denote a delta value of oxidation-reduction reaction of metals with reference to a zero voltage of hydrogen H₂, which may be fixed to each of the metals.

Referring to FIG. 6, metals Sn, Ni, Cd, Fe, Cr, Zn, and/or Al may be positioned on an upper side of the table with reference to hydrogen H₂, which may have a relatively strong oxidation tendency. Metals Cu, Ag and/or Au may be positioned on a lower side of the table with reference to hydrogen H₂, which may have a relatively strong reduction tendency. The lower the metal may be positioned in the table, the lower the ionization tendency may be.

According to embodiments, a metal used to bury deep contact hole 135 may include a metal having an ionization tendency lower relative to a metal of first metal connection portion 115 and/or second metal connection portion 117. In embodiments, a metal of first metal connection portion 115 and/or second metal connection portion 117 may include copper Cu. In embodiments, a metal buried in deep contact hole 135 may include silver Ag and/or gold Au, which may have an ionization tendency lower than copper Cu. At an interface of deep contact 140 and second metal connection portion 117, oxidative and reductive reactions according to the following reaction formulas may occur.

Cu→Cu⁺²+2e Reaction Formula 1

Ag⁺+e→Ag

Au⁺³+3e→Au Reaction Formula 2

According to embodiments, Reaction Formula 1 including an oxidative reaction may emit heat, and/or Reaction Formula 2 including a reductive reaction may absorb heat. In embodiments, first metal connection portion 115 and/or second metal connection portion 117 including copper Cu may emit heat by an oxidative reaction. In embodiments, contact 140 having silver Ag and/or Au including a reductive reaction may absorbs heat. In embodiments, using oxidative and/or reductive reactions, heat emitted at a time of bonding first metal connection portion 115 and second metal connection portion 117 may be absorbed by contact 140. In embodiments, heat absorbed may be dissipated to an outside, for example through an upper side of contact 140 as illustrated in FIG. 5.

According to embodiments, a method of manufacturing a SIP may maximize uniformity of an inside surface of a deep contact hole, for example by treating an inside surface of a deep contact hole with tetra-methyl ammonium hydroxide (TMAH), which may include a strongly alkaline organic substance, and/or nitric acid (HNO₃), which may include a strong acid. In embodiments, a method of manufacturing a SIP may maximize device characteristics, for example by dissipating heat generated at a time of bonding. In embodiments, device characteristics may be maximized by, for example, forming a contact of gold and/or silver which may include a relatively stronger reductive power than, for example, copper.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
providing a first chip comprising a first substrate region and a first metal connection portion;
providing a second chip comprising a second substrate region and a second metal connection portion;
bonding said first metal connection portion with said second metal connection portion;
etching said second substrate region by reactive ion etching to form a deep contact hole exposing at least a portion of said second metal connection portion; and
treating a surface of said deep contact hole with at least one of a alkaline organic substance and an acidic substance.

2. The method of claim 1, wherein:
said first metal connection portion is formed over said first substrate region; and
said second metal connection portion is formed over said second substrate region.

3. The method of claim 1, comprising burying a metal over said deep contact hole including a lower ionization tendency relative to a metal of said first metal connection portion and said second metal connection portion.

4. The method of claim 3, wherein:
said first metal connection portion and said second metal connection portion comprise copper; and
said metal buried over said deep contact hole comprises at least one of silver and gold.

5. The method of claim 1, wherein said first substrate region comprises at least one of a semiconductor device, an insulating layer, a metal line and a metal pad.

6. The method of claim 5, wherein said semiconductor device comprises at least one a transistor, an inductor and a capacitor.

7. The method of claim 1, wherein said first metal connection portion and said second metal connection portion comprise at least one of copper, an alloy of copper and tin.

8. The method of claim 1, wherein:
said alkaline organic substance comprises tetra-methyl ammonium hydroxide; and
said acidic substance comprises nitric acid.

9. The method of claim 8, wherein said tetra-methyl ammonium hydroxide and said nitric acid are applied in succession.

10. The method of claim 9, wherein using said tetra-methyl ammonium hydroxide comprises a time period longer relative to a time period to use said nitric acid.

11. The method of claim 1, wherein bonding said first metal connection portion with said second metal connection portion comprises thermal compressive bonding.

12. The method of claim 1, wherein bonding said first metal connection portion with said second metal stacks said second chip with said first chip.

13. An apparatus comprising:
a first chip comprising a first substrate region and a first metal connection portion, and a second chip comprising a second substrate region and a second metal connection portion, said first metal connection portion bonded with said second metal connection portion;
wherein said second substrate comprises a deep contact hole exposing at least a portion of said second metal connection portion, said deep contact hole comprising a surface treated with at least one of a alkaline organic substance and an acidic substance.

14. The apparatus of claim 13, wherein:
said first metal connection portion is formed over said first substrate region;
said second metal connection portion is formed over said second substrate region; and
said first chip is stacked with said second chip.

15. The apparatus of claim 13, comprising a metal formed over said deep contact hole including a lower ionization tendency relative to a metal of said first metal connection portion and said second metal connection portion.

16. The apparatus of claim 15, wherein:
said first metal connection portion and said second metal connection portion comprise copper; and
said metal over said deep contact hole comprises at least one of silver and gold.

17. The apparatus of claim 13, wherein said first substrate region comprises at least one of a semiconductor device, an insulating layer, a metal line and a metal pad.

18. The apparatus of claim 17, wherein said semiconductor device comprises at least one a transistor, an inductor and a capacitor.

19. The apparatus of claim 13, wherein said first metal connection portion and said second metal connection portion comprise at least one of copper, an alloy of copper and tin.

20. The apparatus of claim 13, wherein:
said alkaline organic substance comprises tetra-methyl ammonium hydroxide; and
said acidic substance comprises nitric acid.
